(19) United States
(12) Patent Application Publication
(10) Pub. No.: US 2023/0078697 A1
(43) Pub. Date: Mar. 16, 2023

(54) METHOD AND APPARATUS FOR DETERMINING DISPLAY POWER, ELECTRONIC DEVICE, AND STORAGE MEDIUM

(71) Applicant: GUANGDONG OPPO MOBILE TELECOMMUNICATIONS CORP., LTD., Dongguan (CN)

(72) Inventors: Shaobin Liu, Dongguan (CN); Zhenming Yang, Dongguan (CN)

(21) Appl. No.: 17/992,539

(22) Filed: Nov. 22, 2022

Related U.S. Application Data
(63) Continuation of application No. PCT/CN2021/096046, filed on May 26, 2021.

(30) Foreign Application Priority Data
May 26, 2020 (CN) 202010454412.8

(51) Int. Cl. H02J 7/00

(52) U.S. Cl. CPC H02J 7/0048

(57) ABSTRACT

Provided are a method and an apparatus for determining a display power, an electronic device, and a storage medium. The method includes: determining, based on a first pin of a charging chip, a first voltage characterizing a voltage of the first pin when a battery is in a fully charged state, and the first pin being a battery pin of the charging chip; determining, based on the first voltage, a first relationship characterizing a corresponding relationship between the voltage of the first pin and a power of the battery; and determining, based on the first relationship according to the voltage of the first pin, a display power of the battery.

### CROSS-REFERENCE TO RELATED APPLICATIONS

This application is a continuation of International Application No. PCT/CN2021/096046, filed on May 26, 2021, which is based on and claims priority to Chinese Patent Application No. 202010454412.8 filed on May 26, 2020, the entire disclosure of which is incorporated herein by reference.

### FIELD

The present disclosure relates to the field of battery technologies, and more particularly, to a method and an apparatus for determining a display power, an electronic device, and a storage medium.

### BACKGROUND

At present, when a power of a battery is displayed in an electronic device, there is a phenomenon in which a display power does not match with an actual power. In this case, it is difficult to display that a fully charged battery is in a fully charged state when the battery is fully charged, thereby affecting user experience.

### SUMMARY

In order to solve the related technical problem, embodiments of the present disclosure provide a method for determining a display power, a terminal, and a storage medium.

Embodiments of the present disclosure provide a method for determining the display power. The method includes: determining, based on a first pin of a charging chip, a first voltage characterizing a voltage of the first pin when a battery is in a fully charged state, the first pin being a battery pin of the charging chip; determining, based on the first voltage, a first relationship characterizing a correspondence between the voltage of the first pin and a power of the battery; and determining, based on the first relationship, the display power of the battery using the voltage of the first pin.

Embodiments of the present disclosure further provide another method for determining a display power. The method incudes: powering a charging chip in response to a charging function of the charging chip being enabled, and collecting a first voltage external to a first pin of the charging chip, the first pin being externally opened during the collecting of the first voltage, and the first pin is a battery pin of the charging chip; and determining, based on the first voltage, a first relationship characterizing a correspondence between a voltage of the first pin and a power of the battery to allow an electronic device to determine the display power of the battery based on the voltage of the first pin.

Embodiments of the present disclosure further provide an electronic device. The electronic device includes a processor, and a memory storing a computer program executable on the processor. The processor is configured to implement, when executing the computer program, steps of the method for determining the display power as described above.

### BRIEF DESCRIPTION OF THE DRAWINGS

FIG. 1 is a schematic implementation flowchart showing a method for determining a display power according to an embodiment of the present disclosure.

FIG. 2 is a schematic structural diagram showing a charging chip according to an embodiment of the present disclosure.

FIG. 3 is a schematic connection diagram showing each pin of a charging chip according to an embodiment of the present disclosure.

FIG. 4 is a schematic implementation flowchart showing a method for determining a display power according to an embodiment of the present disclosure.

FIG. 5 is a schematic implementation flowchart showing a method for determining a display power according to another embodiment of the present disclosure.

FIG. 6 is a schematic implementation flowchart showing a method for determining a display power according to another embodiment of the present disclosure.

FIG. 7 is a schematic implementation flowchart showing a method for determining a display power according to another embodiment of the present disclosure.

FIG. 8 is a schematic implementation flowchart showing a method for determining a display power according to another embodiment of the present disclosure.

FIG. 9 is a schematic implementation flowchart showing a method for determining a display power according to another embodiment of the present disclosure.

FIG. 10 is a schematic implementation flowchart showing a method for determining a display power according to another embodiment of the present disclosure.

FIG. 11 is a schematic implementation flowchart showing a method for determining a display power according to a further another embodiment of the present disclosure.

FIG. 12 is a schematic diagram showing a true wireless stereo earphone and an earphone box according to an embodiment of the present disclosure.

FIG. 13 is a schematic structural diagram showing an apparatus for determining a display power according to an embodiment of the present disclosure.

FIG. 14 is a schematic structural diagram showing an apparatus for determining a display power according to another embodiment of the present disclosure;

FIG. 15 is a schematic structural diagram showing hardware composition of an electronic device according to an embodiment of the present disclosure.

### DETAILED DESCRIPTION

In the related art, typically, there are two methods for determining a display power of a battery, and displaying the determined display power. One method is to accurately count a power of the battery through a power meter, and determine a display power of the battery according to a statistical result, to display the power of battery. The other method is to determine powers of the battery corresponding to different voltages during charging and discharging based on a charging and discharging curve. In practical applications, the display power is generally determined by using the second method. A nominal charging cut-off voltage is provided on a charging chip. During the charging, when a battery pin of the charging chip reaches the charging cut-off voltage, the battery is determined in a fully charged state. For various reasons, when the nominal charging cut-off voltage is the same, actual charging cut-off voltages corresponding to different charging chips have an error range of 0 .05V. For example, when a power of a battery of a wireless stereo earphone is displayed, since there are many manufacturers of the wireless stereo earphone, the charging chips equipped in the wireless stereo earphones provided by different manufacturers are different from each other, and thus the charging cut-off voltages corresponding to the different charging chips are different from each other, which may result in a difference in display power of a left earphone and a right earphone of a pair of TWS earphones. When an actual charging cut-off voltage corresponding to the charging chip is different from the nominal charging cut-off voltage, if the display power of the battery is still determined by using a correspondence between a voltage established based on the nominal charging cut-off voltage and the power, a determined display power of the battery may be different from an actual power of the battery. Thus, it is impossible to accurately determine battery consumption according to the display power, resulting in a plurality of charging operations, and thus service life of a battery of an electronic device is shortened and user's use is affected.

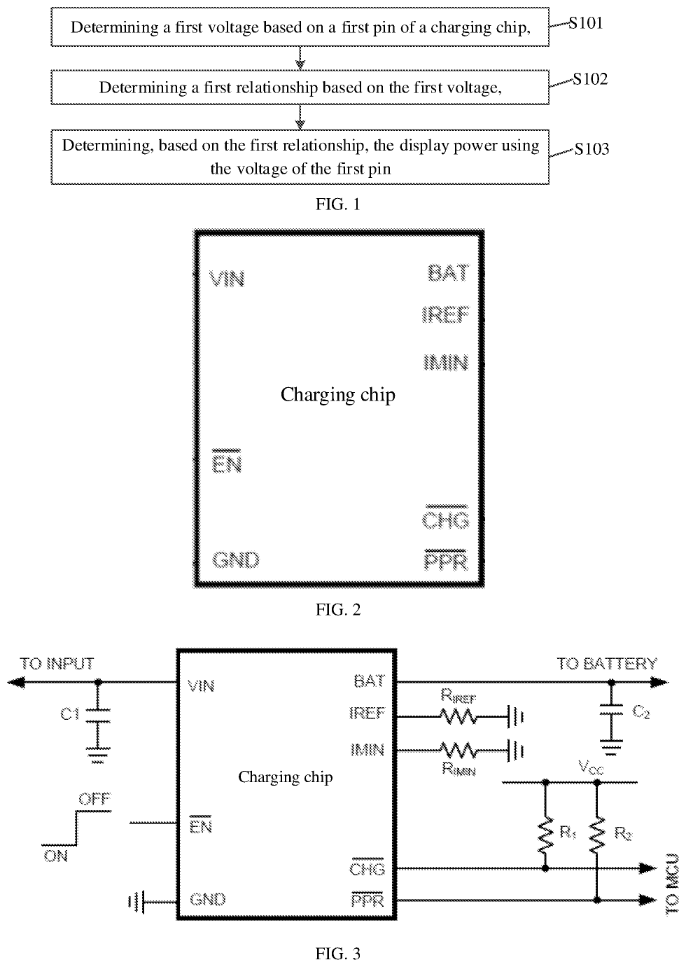

In view of the above, embodiments of the present disclosure provide a method for determining a display power. FIG. 1 illustrates an implementation flow of the method for determining a display power according to an embodiment of the present disclosure. As illustrated in FIG. 1, the method includes actions at S101 to S103.

At S101, a first voltage is determined based on a first pin of a charging chip. The first voltage characterizes a voltage of the first pin when a battery is in a fully charged state. The first pin is a battery pin of the charging chip.

The charging chip is a chip capable of charging and controlling the battery. During the charging of the battery by the charging chip, when the battery reaches a voltage in the fully-charged state, a voltage collected at the battery pin of the charging chip is a charging cut-off voltage of the charging chip. The first pin is the battery pin of the charging chip. The charging chip is connected to the battery through the first pin to provide a charging current and a charging voltage to the battery. Further, the charging chip can determine a first voltage of the battery in the fully charged state by detecting a voltage of the first pin of the charging chip. As illustrated in FIG. 2, a schematic view of the charging chip is illustrated. A BAT pin in FIG. 2 is the battery pin of the charging chip, i.e., the first pin. When the battery reaches the fully charged state, a voltage of the BAT pin is the first voltage of the battery in the fully charged state. For example, when the battery is in the fully charged state, it is detected that the voltage of the first pin of the charging chip is 4.3 V, and thus the first voltage may be determined as 4.3 V. In practical applications, due to various reasons such as a manufacturing process, a situation in which the first voltage determined based on the first pin of the charging chip is different from a nominal charging cut-off voltage of the charging chip may occur. By detecting the voltage of the first pin of the charging chip when the battery is in the fully charged state, an actual cut-off voltage of the charging chip can be determined. For example, the nominal charging cut-off voltage of the charging chip is 4.3 V, and the first voltage determined by the first pin of the charging chip is 4.25 V.

In one embodiment, determining, based on the first pin of the charging chip, the first voltage includes: detecting, in response to a second pin of the charging chip characterizing that the battery is in a fully charged state, the voltage of the first pin, and determining the detected voltage of the first pin as the first voltage. The second pin characterizes a charging state of the battery. The determining a first relationship based on the first voltage includes: determining, in response to the first voltage being different from the nominal charging cut-off voltage of the charging chip, the first relationship based on the first voltage.

The second pin of the charging chip is a charging state indication end of an open drain output, and the charging state of the battery can be represented by an output voltage of the second pin. When the second pin characterizes that the battery is in the fully charged state, the battery is indicated to have been in a specific fully charged state, and continuous charging may not enable a charging reaction of the battery to be continuously performed. In practical applications, whether the battery is in the fully charged state may be determined according to a change of the output voltage of the second pin. For example, in some charging chips, when the battery is in the fully charged state, the voltage of the first pin of the charging chip represents the voltage of the battery in the fully charged state, the voltage of the first pin of the charging chip is detected, and the detected voltage of the first pin is determined as the first voltage. When the first relationship is determined based on the first voltage, the first voltage is compared with the nominal charging cut-off voltage of the charging chip. In response to the first voltage being different from the nominal charging cut-off voltage of the charging chip, it is indicated that when the battery is in the fully charged state, the voltage of the first pin corresponding to the charging chip is the first voltage, rather than the nominal charging cut-off voltage of the charging chip. The first relationship is determined according to the first voltage, and thus a display power in the fully charged state can be determined. As illustrated in FIG. 3, a schematic connection diagram showing each pin of the charging chip is illustrated. The BAT pin of the chip is the first pin. A CHG pin of the chip is the second pin, which can represent the charging state of the battery. The CHG pin of the chip is connected to a processor. The processor is capable of recording a variation of the CHG pin of the chip. The processor can detect, in response to detecting that the CHG pin of the chip characterizes that the battery is in the fully charged state, an output voltage of the BAT pin of the chip, to determine the first voltage. For example, when it is detected that an output voltage of the BAT pin of the chip is 4.25 V, it may be determined that the first voltage is 4.25 V. In practical applications, depending on reasons like a type of the charging chip, manufacturer, etc., when the output voltage of the second pin is at a high level, this represents that the battery is in the charging state. When the output voltage of the second pin is at a low level, this represents that the battery is in the fully charged state. When the second pin is converted from the high level to the low level and the battery is in the fully charged state, the voltage of the first pin is detected. There is another case where when the output voltage of the second pin is at the low level, it represents that the battery is in the charging state. When the output voltage of the second pin is at the high level, it represents that the battery has been in the fully charged state. When the second pin is converted from the low level to the high level and the battery is in the fully charged state, the voltage of the first pin is detected.

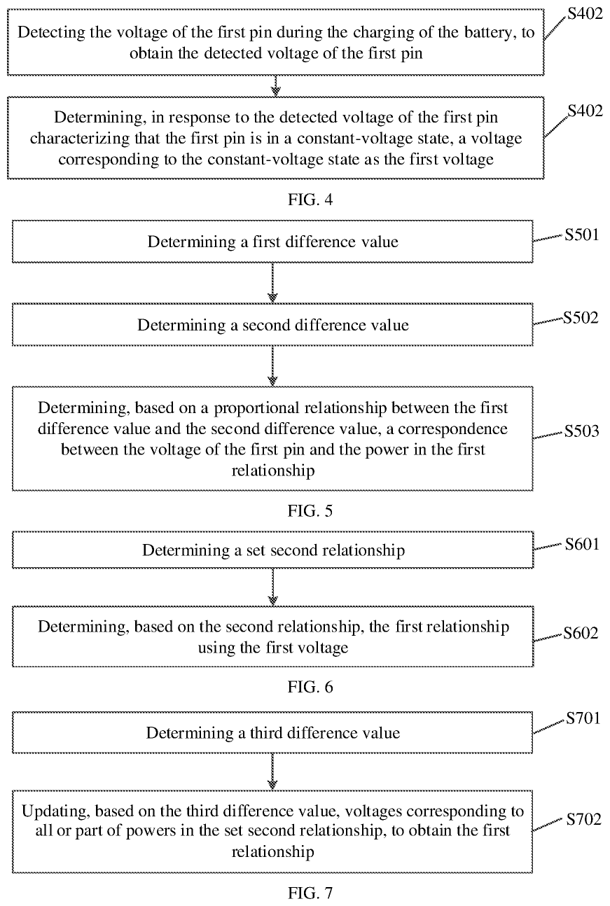

In one embodiment, as illustrated in FIG. 4, determining the first voltage based on the first pin of the charging chip includes actions at S401 and S402.

At S401, during the charging of the battery, the voltage of the first pin is detected to obtain the detected voltage of the first pin.

During the charging of the battery, there are three stages including a pre-charging stage, a constant-current stage, and a constant-voltage stage. In different stages, the voltage of the first pin of the charging chip may change, and the voltage of the first pin is detected to obtain a corresponding detected voltage of the first pin.

At S402, in response to the detected voltage of the first pin characterizing that the first pin is in the constant-voltage state, a voltage corresponding to the constant-voltage state is determined as the first voltage.

During the charging of the battery, a last stage is the constant-voltage stage. When entering the constant-voltage stage, a charging voltage of the battery is kept constant. Moreover, the charging voltage of the battery in the constant-voltage stage may generally be regarded as the charging cut-off voltage of the charging chip. After obtaining the detected voltage of the first pin during the charging of the battery, the detected voltage is analyzed. When the detected voltage of the first pin indicates that the first pin is in the constant-voltage state, it is indicated that the battery is in the constant-voltage stage of the charging process, and the voltage corresponding to the constant-voltage state is determined as the first voltage, i.e., the cut-off voltage of the charging chip. The constant-voltage state may be determined by the detected voltage of the first pin. In some embodiments, when the voltages of the first pin at different time points are continuously detected to be same as each other, it may be considered that the first pin is in the constant-voltage state. For example, when it is detected that voltages of the first pin at different time points are 3.5 V, 4.0 V, 4.25 V, 4.25 V, 4.25 V, respectively, since the voltage of 4.25 V occurs server times in the detected voltage of the first pin and remain unchanged for a period of time, it may be determined that the first pin has already been in the constant-voltage state, and the voltage of 4.25 V is the first voltage. In practical applications, a time cycle for detecting the first pin may be provided in the charging process. For example, the voltage of the first pin is detected every 30 s. When the voltages of the first pin at different time points are the same as each other, it may be observed whether the voltage of the first pin remains unchanged for a period of time. For example, the voltages of the first pin within 2 min may be observed. The first voltage of the battery chip of the battery can be determined when the batter is in the constant-voltage stage of the charging process. Therefore, instead of determining the first voltage of the battery chip only when the charging of the battery is completed, the first voltage of the battery chip can be quickly determined.

At S102, the first relationship is determined based on the first voltage. The first relationship characterizes a correspondence between the voltage of the first pin and the power of the battery.

After the first voltage is determined, the first relationship is determined based on the first voltage. The first relationship may be represented in a form of a first relational table, and records the correspondence between the voltage of the first pin and the power of the battery by using the first relational table; or may be represented in a form of a calculation formula, and calculates a power of the battery corresponding to the voltage of the first pin by using a first relational expression. For example, when the determined first voltage is 4.25 V, since the first voltage corresponds to a voltage of the battery in the fully charged state, when the relational table is established, a power of the battery corresponding to the voltage of 4.25 V may be determined to be 100%, and voltages of the battery corresponding to different powers is determined based on the first voltage, to establish the first relational table.

In one embodiment, as illustrated in FIG. 5, when determining the first relationship based on the first voltage, the method includes actions at S501 to S503.

At S501, a first difference value is determined. The first difference value characterizes a difference value between the first voltage and a second voltage. The second voltage characterizes a voltage of the first pin corresponding to a minimum power required by the battery for maintaining a normal operation of an electronic device.

The electronic device may refer to a device powered by the battery. The battery may be a rechargeable battery. For example, the device includes a wireless stereo earphone, a sound box, a mobile phone, a tablet computer, a notebook computer, etc. After determining the first voltage, the difference value between the first voltage and the second voltage is determined to obtain the first difference value. The second voltage refers to a voltage of the first pin corresponding to the minimum power required by the battery for maintaining the normal operation of the electronic device. For example, the second voltage may be a voltage of the first pin of the battery chip when the display power of the battery is 0%. When a remaining power of the battery of the electronic device reaches the minimum power required for maintaining the normal operation of the electronic device, the electronic device stops operating, and the display power is 0% when the electronic device stops operating. In order to avoid a negative impact on the service life of the battery due to repeated depletion of the power of the battery, in practical applications, the minimum power required for maintaining the normal operation of the electronic device may be set, so that when the display power of the electronic device reaches 0%, the battery of the electronic device also has a remaining power. As illustrated, when the battery is in the fully charged state, a voltage corresponding to a first pin of a power supply chip is the first voltage. When the display power of the battery is 0%, the voltage corresponding to the first pin of the power supply chip is the second voltage. For example, when the battery is in the fully charged state, the corresponding first voltage is 4.25 V, and when the display power of the battery is 0%, the corresponding second voltage is 3.3 V, and it may be determined that the first difference value is 0.95 V.

At S502, a second difference value is determined. The second difference value characterizes a difference value between the voltage of the first pin and the second voltage.

The voltage of the first pin characterizes a measured voltage corresponding to the battery. The difference value between the voltage of the first pin and the second voltage is determined as the second difference value. The first voltage is the voltage of the first pin when the battery is in the fully charged state. The second voltage is the voltage of the first pin when the power of the battery is exhausted. A voltage range in the first relationship is determined by the first voltage and the second voltage. Therefore, the voltages of the first pin corresponding to different powers fall into the voltage range determined by the first voltage and the second voltage. For example, when the first voltage is 4.25 V and the second voltage is 3.3 V, the value range of the voltage in the first relationship is determined as [3.3V, 4.25V] by the first voltage and the second voltage determine. Thus, it may be determined that the voltage of the first pin has a voltage value in a range of [3.3V, 4.25V]. For example, when the voltage of the first pin is 3.4 V, it may be determined that the second difference value between the second voltage of 3.3 V and the voltage of 3.4 V of the first pin is 0.1 V.

At S503, a correspondence between the voltage of the first pin and the power in the first relationship is determined based on a proportional relationship between the first difference value and the second difference value.

According to the proportional relationship between the first difference value and the second difference value, the power of battery corresponding to the voltage of the first pin within the voltage range determined by the first voltage and the second voltage may be determined, to determine the first relationship. In practical applications, the first relationship may be the first relational table or the first relational expression, as long as a relationship between the voltage of the first pin and the display power can be characterized. For example, the first relational expression for obtaining the display power may be expressed as

$$P = \frac{{D}_{2}}{{D}_{1}} \times 100 \% ,$$

where P represents the power corresponding to the voltage of the first pin and represents a magnitude of the power in percentage, D₁ represents the first difference value, and D₂ represents the second difference value. By using an algorithm expression of the power, the power corresponding to the voltage of the first pin can be determined, and thus the correspondence between the power and the voltage in the first relationship can be determined. For example, when the first voltage is 4.25 V, the second voltage is 3.3 V, and the voltage of the first pin is 3.4 V, it is determined that the first difference value is 0.95 V, and the second difference value is 0.1 V. According to

$$P = \frac{{D}_{2}}{{D}_{1}} \times 100 \% = \frac{0.1 V}{0.95 V} \times 100 \% = 11 \% ,$$

it is determined that the corresponding power is 11% when the voltage of the first pin is 3.4 V. Of course, according to the above relationship, by detecting the voltages of different first pins, the powers corresponding to the voltages of the different first pins may be determined to generate the first relational table. Table 1 is the first relational table established based on the proportional relationship between the first difference value and the second difference value.

TABLE 1

| Voltage (V) | Power |
|---|---|
| 4.25 | 100% |
| 4.2 | 95% |
| 4.1 | 84% |
| 4 | 74% |
| 3.9 | 63% |
| 3.8 | 53% |
| 3.7 | 42% |
| 3.6 | 32% |
| 3.5 | 21% |
| 3.4 | 11% |
| 3.3 | 0% |

In one embodiment, as illustrated in FIG. 6, determining, based on the first voltage, the first relationship includes actions at S601 and S602.

At S601, a set second relationship is determined. In the second relationship, a first power characterizing a fully charged power of the battery corresponds to a third voltage characterizing the nominal charging cut-off voltage of the charging chip.

The set second relationship is determined herein. The second relationship is a correspondence between a voltage determined based on the third voltage and the power. The third voltage represents the nominal cut-off voltage of the charging chip. In practical applications, there are charging chips of different specifications. Different charging chips mainly include different nominal charging cut-off voltages. When selecting the charging chip, a charging chip of a proper nominal charging cut-off voltage is usually selected based on a type and parameters of the battery, to manage the battery better. In the second relationship, the voltage corresponding to the first power is the third voltage. The first power refers to the fully charged power of the battery. That is, the voltage when the power of the battery is 100% is the third voltage. In practical applications, the electronic device may have been configured with the correspondence, between the voltage and the power determined based on the nominal charging cut-off voltage before leaving factory, i.e., the second relationship. Thus, according to the correspondence between the voltage and the power in the second relationship, the power of the battery is displayed. The second relationship may be in a form of a second relational table or in a form of a second relational expression. For example, taking the second relational table as an example, when the nominal cut-off voltage of the charging chip is 4.3 V, Table 2 shows a set second relational table. In Table 2, a voltage corresponding to the fully charged power of the battery is the third voltage.

TABLE 2

| Voltage (V) | Power |
|---|---|
| 4.3 | 100% |
| 4.2 | 90% |
| 4.1 | 80% |
| 4 | 70% |
| 3.9 | 60% |
| 3.8 | 50% |
| 3.7 | 40% |
| 3.6 | 30% |
| 3.5 | 20% |
| 3.4 | 10% |
| 3.3 | 0% |

At S602, the first relationship is determined based on the second relationship using the first voltage.

After determining the set second relationship, the correspondence between the voltage and the power in the second relationship is adjusted based on the second relationship using the first voltage, to determine the first relationship on the basis of the second relationship. In practical applications, in response to the first voltage being different from the second voltage, the first relationship may be determined based on the second relationship using the first voltage. That is, in response to the actual charging cut-off voltage of the charging chip being different from the nominal charging cut-off voltage of the charging chip, the correspondence between the voltage and the power is determined according to the actual charging cut-off voltage of the charging chip to generate the first relationship is generated. Thus, the display power of the power can be determined.

In one embodiment, determining, based on the second relationship, the first relationship using the first voltage includes: updating, with the first voltage, the voltage corresponding to the first power in the second relationship, to obtain the first relationship.

When the first relationship is determined based on the second relationship using the first voltage, the voltage corresponding to the first power in the second relationship is modified to the first voltage, to dynamically adjust the correspondence between the voltage and the fully charged power based on the actual charging cut-off voltage of the charging chip. When displaying the power of the battery, it is possible to accurately display the power of the battery is in the fully charged power state. For example, taking the second relationship being the form of the second relational table as an example, when the first voltage is 4.25 V and the third voltage is 4.3 V, and when the relationship between the voltage and the power of the battery is not adjusted, the correspondence between the power and the voltage of the battery is determined in the set second relational table during the determining of the display power. Since the first voltage is 4.25 V, which means that when the voltage of the first pin of the charging chip is 4.25 V, the battery is in the fully charged state, and the power of the battery is 100%. When it may be determined that the voltage is 4.25 V in the set second relational table, the power of the battery is 95% correspondingly. That is, it is determined that the display power of the battery is 95%, and thus the display power is 95%, which can not accurately display the power of the battery. Moreover, since the charging cut-off voltage of the charging chip is 4.25 V, the battery is stopped charging when the voltage reaches 4.25 V. In this case, the voltage of the first pin of the charging chip can not reach 4.3 V. Therefore, when determining the display power of the battery based on the set second relational table, the power of the battery of 100% can not be displayed, which may make the user mistakenly consider that there is a problem with the battery. The voltage corresponding to the first power in the set second relational table is modified to the first voltage, so that the voltage corresponding to the power of 100% is 4.25 V. In this case, the fully charged power of the battery can be accurately displayed according to the determined display power of the battery. In practical applications, it may be determined whether the first voltage is the same as the third voltage first. In responses to the first voltage being different from the third voltage, the voltage corresponding to the first power in the second relationship is updated with the first voltage to obtain the first relationship. When the first voltage is the same as the third voltage, the voltage corresponding to the first power in the second relationship is not required to be updated, and the display power of the battery can be directly determined based on the second relationship.

In one embodiment, as illustrated in FIG. 7, determining, based on the second relationship, the first relationship using the first voltage includes actions at S701 and S702.

At S701, a third difference value is determined. The third difference value characterizes a difference value between the first voltage and the third voltage.

The third difference value is determined according to the first voltage and the third voltage. When the first voltage is the same as the third voltage, the third difference value is zero, in response to the first voltage being different from the third voltage, it can be determined that the third difference value is a value greater than zero. For example, when the first voltage is 4.25 V and the third voltage is 4.3 V, it can be determined that the third difference is 0.05 V.

At S702, a voltage corresponding to all or part of the powers in the second relationship is updated based on the third difference value, to obtain the first relationship. The part of the powers includes the first power.

Taking the form of the second relational table as an example, after the third difference value is determined, the voltage corresponding to each power in the second relational table is adjusted according to the third difference value. The correspondence between the adjusted voltage and the power is determined as the first relational table. In practical applications, adjusting the voltage corresponding to each power in the second relational table is mainly to decrease the voltage corresponding to each power in the second relational table by the third difference value as a decremental amplitude. For example, when the voltage corresponding to the power of 0% in the set second relational table is 3.3 V. This voltage of 3.3V is decreased based on the third difference value, and thus the updated voltage corresponding to the power of 0% is 3.25 V. The first relational table can be obtained by adjusting the voltage corresponding to each power in the set second relational table. Table 3 is the first relational table generated based on the set second relational table according to the third difference value. In Table 3, the voltage corresponding to each power in the first relational table is obtained by reducing the voltage corresponding to each power in the set second relational table by the third difference value. In addition to updating the voltage corresponding to each of the powers in the second relational table, the voltages corresponding to some of the powers in the second relational table may be updated to obtain the first relational table. When the voltages corresponding to the part of the powers are updated, the voltage corresponding to the first power is at least updated, thereby ensuring that it is possible to display the power of the battery is in the fully charged state. For example, only the voltage corresponding to the fully charged power (the power of 100%) in the second relational table and a voltage corresponding to the power at which the electronic device can not maintain the normal operation are updated. In practical applications, when the first voltage is the same as the third voltage, the third difference value is zero. Since the voltage corresponding to each after the adjustment according to the third difference value is the same as that in the second relational table, on this basis, the second relational table is not required to be adjusted to generate the first relational table, and the display power of the battery can be directly determined based on the second relational table. Therefore, a processing time and power consumption of a terminal can be saved. Of course, the second relationship may also exist in a form of the second relational expression, and the corresponding display power may be calculated based on the third difference value after measuring the voltage of the first pin, instead of obtaining by looking up the table. A calculation principle is the same as that of the second relational table, and details thereof will be omitted herein.

TABLE 3

| Voltage (V) | Power |
|---|---|
| 4.25 | 100% |
| 4.15 | 90% |
| 4.05 | 80% |
| 3.95 | 70% |
| 3.85 | 60% |
| 3.75 | 50% |
| 3.65 | 40% |
| 3.55 | 30% |
| 3.45 | 20% |
| 3.35 | 10% |
| 3.25 | 0% |

At S103, the display power of the battery is determined based on the first relationship according to the voltage of the first pin.

The display power of the battery is determined through the first relationship according to the voltage of the first pin. The correspondence between the voltage of the first pin of the charging chip and the power of the battery is accurately recorded in the first relationship. After the voltage of the first pin of the charging chip is determined, the power corresponding to the voltage of the first pin of the charging chip is determined as the display power of the battery through the first relationship, and the electronic device may display the display power on a corresponding interface. For example, taking the first relationship represented by the first relational table as an example, when it is detected that the voltage of the first pin of the charging chip is 4.25 V, the power corresponding to the voltage value of 4.25 V is searched in the first relational table. When the power corresponding to the voltage of 4.25 V is determined to be 100% in the first relational table, it may be determined that the display power of the battery is 100%. Based on the display power of the battery, a current power of the battery is displayed as 100%. In practical applications, a display power of a battery of a wireless stereo device such as a true wireless stereo (TWS) earphone, a wireless mouse may be determined. For example, in practical applications, a pair of TWS earphones are equipped with a left TWS earphone and a right TWS earphone. When a power of the battery of each TWS earphone is displayed on a mobile terminal (such as a mobile phone, a tablet computer, a smart watch, etc.) connected to the earphone, the TWS earphone determines a power corresponding to a voltage of a first pin of a charging chip of the TWS earphone, i.e., that is, a display power of the TWS earphone, based on the first relational table, and transmits the corresponding power to the mobile terminal (generally, a main earphone of the pair of TWS earphones is in communication with the mobile terminal to upload data to the mobile terminal from the pair of TWS earphones through the main earphone) in a communication manner such as via a Bluetooth. After receiving related information, the mobile terminal displays the power of the battery of the TWS earphone in real time on a display interface of the power of the battery of the mobile terminal. The power of the battery of the TWS earphone may also be displayed on a charging box. The TWS earphone determines the power corresponding to the voltage of the first pin of the charging chip of the TWS earphone according to the first relational table, and transmits the power to the charging box in a wireless communication manner such as via the Bluetooth or in a wired manner such as via a touch point and an interface. After receiving related data, the charging box displays the power of the battery of the TWS earphone.

In the embodiments of the present disclosure, the first voltage is determined based on the first pin of the charging chip. The first voltage characterizes the voltage of the first pin when the battery is in the fully charged state, and the first pin is a battery pin of the charging chip. The first relationship is determined based on the first voltage. The first relationship characterizes a correspondence between the voltage of the first pin and the power of the battery. Based on the first relationship, the display power of the battery is determined according to the voltage of the first pin. The correspondence between the voltage and the power of the battery may be determined according to the voltage of the first pin of the charging chip when the battery is in the fully charged state, to determine the display power of the battery and accurately display the power of the battery. Therefore, a use condition of the power of the battery may be accurately judged according to the display power. When applied in the TWS earphone, it is possible to reduce the following influences on the user in a case where the left and right earphones adopt charging ICs having different nominal charging cut-off voltages (namely, the third voltage). Firstly, the powers of the fully charged left and right earphones are different from each other, for example, one of the earphones is fully charged under extreme condition, and the other is only charged to 95%. Secondly, since the powers of the fully charged earphones are different, when the two earphones are used at the same time, displayed remaining battery levers of the left and right earphones are also different, which may notify the user that one of the earphones has a fast power consumption, and the other has a low power consumption, thereby misleading the user into considering that the one of the earphones is broken. Thirdly, the user may perform more frequent charging due to inaccurate displaying of the power, thereby affecting the service life of the battery. Therefore, the user experience can be improved according to the embodiments of the present disclosure.

The above embodiments illustrate that after the electronic device leaves factory, the displaying of the power of the battery is calibrated during use. Embodiments of the present disclosure further provides a setting method for calibrating the displaying of the power of the battery before leaving factory. It should be noted that the above-mentioned solutions after leaving factory and the following solutions before leaving factory may be applied together. That is, when leaving factory, according to the solutions before leaving factory, an accuracy of the displaying of the power of the battery during using by the user can be ensured. In practical use after leaving factory, the accuracy of the displaying of the power of the battery during each charging and discharging process can be ensured according to the above-mentioned solution after leaving factory.

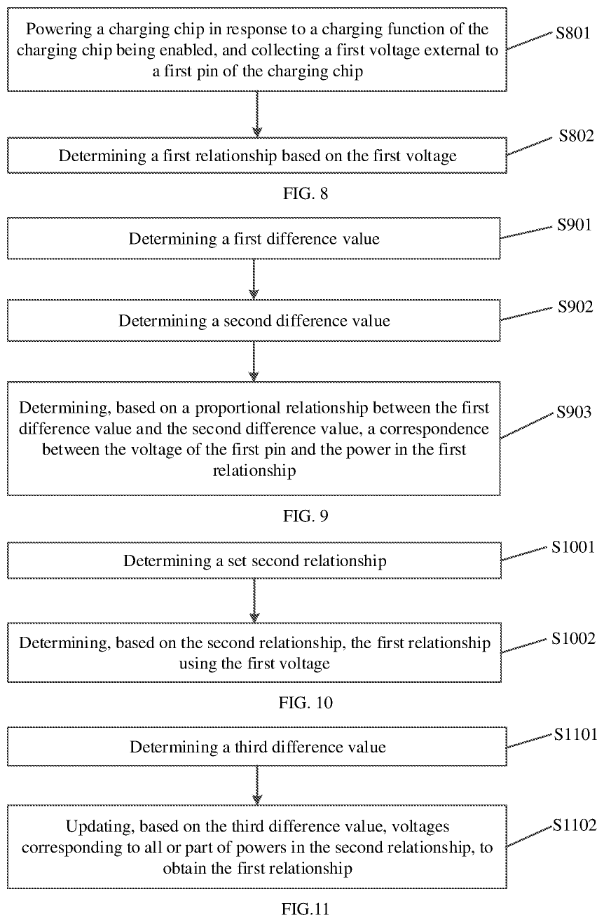

In one embodiment, as illustrated in FIG. 8, determining the display power includes actions at S801 and S802.

At S801, in response to a charging function of the charging chip being enabled, the charging chip is powered, and a first voltage external to the first pin of the charging chip is collected. The first pin is externally opened during the collecting of the first voltage. The first pin is the battery pin of the charging chip.

The charging function of the charging chip is controlled by an enabling end of the charging chip to allow the charging chip to turn on or turn off the charging function. In the case where the charging function of the charging chip is enabled, an external power supply is provided to the charging chip. In a state in which the first pin is externally opened, the voltage of the first pin of the charging chip is collected. Since the first pin is in the open-circuit state, the collected voltage of the first pin in this case may be regarded as the charging cut-off voltage of the charging chip. The first pin is the battery pin of the charging chip and a pin connected to a battery end. Taking the schematic diagram of the charging chip in FIG. 3 as an example, an EN pin of the charging chip is used to control the charging function of the charging chip. When a high level is input to the EN pin, the charging function of the charging chip is disenabled. When a low level is input to the EN pin, the charging function of the charging chip is enabled. When measuring the charging cut-off voltage of the charging chip, the low level is required to be input to the EN pin of the charging chip, and the external power supply is connected to a VIN pin of the charging chip, and a BAT pin of the charging chip is in the open-circuit state. After the charging chip is powered, a voltage of the BAT pin of the charging chip is collected. The collected voltage of the BAT pin of the charging chip is determined as the first voltage. Therefore, the first voltage can be quickly obtained. In practical applications, when a printed circuit board assembly (PCBA) end test is performed on the charging chip, the voltage of the BAT pin of the charging chip in the open-circuit state may be collected in the manner as described above.

At S802, the first relationship is determined based on the first voltage. The first relationship characterizes the correspondence between the voltage of the first pin and the power of the battery to allow the electronic device to determine the display power of the battery based on the voltage of the first pin.

After the first voltage is determined, the first relationship is determined based on the first voltage. The first relationship characterizes the correspondence between the voltage of the first pin and the power of the battery. The first relationship may be in the form of the first relational table or the first relational expression. Through the first relationship, the electronic device can determine the display power of the battery according to the voltage of the first pin. In some embodiments, a correspondence is generated between the first voltage and the power of the battery of 100%, and the correspondence between the first voltage and the power of 100% is determined. Therefore, voltages of the first pin corresponding to other powers may be determined. Taking the first relational table as an example, in practical applications, in order to avoid errors, voltages of the first pin corresponding to the powers with a difference value of 10% are usually determined. For example, after a voltage of the first pin corresponding to the power of 100% is determined, a voltage of the first pin corresponding to the power of 90% is determined. Thus, the first relational table can be determined. The first relational table is stored to enable the electronic device to determine the display power of the battery based on the stored first relational table according to the voltage of the first pin.

In one embodiment, as illustrated in FIG. 9, when determining the first relationship based on the first voltage, the method includes actions at S901 to S903.

At S901, a first difference value is determined. The first difference value characterizes a difference value between the first voltage and the second voltage. The second voltage characterizes the voltage of the first pin corresponding to the minimum power required by the battery for maintaining the normal operation of the electronic device.

The first difference value between the first voltage and the second voltage is determined. The second voltage refers to the voltage of the first pin corresponding to the minimum power required by the battery for maintaining the normal operation of the electronic device. The second voltage may be the voltage of the first pin of the battery chip when the display power is 0%. When the remaining power of the battery of the electronic device reaches the minimum power required for maintaining the normal operation of the electronic device, the electronic device is control to stop operating, and display power is 0% when the electronic device stops operating. In order to avoid the negative impact on the service life of the battery due to repeated depletion of the power of the battery, in practical applications, the minimum power required for maintaining the normal operation of the electronic device may be set, so that when the display power of the electronic device reaches 0%, the battery of the electronic device still has a remaining power. As illustrated, when the battery is in the fully charged state, the voltage corresponding to the first pin of the power supply chip is the first voltage, and when the display power of the battery is 0%, the voltage corresponding to the first pin of the power supply chip is the second voltage. For example, when the battery is in the fully charged state, the first voltage is 4.25 V, and when the display power is 0%, the second voltage is 3.3 V, and it may be determined that the first difference value is 0.95 V.

At S902, a second difference value is determined. The second difference value characterizes a difference value between the voltage of the first pin and the second voltage.

The second difference value is determined by the difference value between the voltage of the first pin and the second voltage. The voltage of the first pin characterizes a measured voltage corresponding to the battery. After the first voltage and the second voltage are determined, a voltage range determined by the first voltage and the second voltage is a value range of voltages corresponding to different powers in the first relationship. All the voltages of the first pin fall within the voltage range determined by the first voltage and the second voltage. For example, when the first voltage is 4.25 V and the second voltage is 3.3 V, the voltage of the first pin may be a value in the range of [3.3, 4.25]. For example, a voltage of 3.6V is selected as the voltage of the first pin, and thus it may be determined that the second difference value is 0.3.

At S903, a correspondence between the voltage of the first pin and the power in the first relationship is determined based on a proportional relationship between the first difference value and the second difference value.

After the first difference value and the second difference value is determined, the power corresponding to the voltage of the first pin can be determined according to the proportional relationship between the first difference value and the second difference value, thereby enabling the first relationship to be determined. Taking the first relational expression as an example, the proportional relationship between the first difference value and the second difference value is

$$P = \frac{{D}_{2}}{{D}_{1}} \times 100 \% ,$$

where P represents the power corresponding to the voltage of the first pin and represents the magnitude of the power in percentage, D₁ represents the first difference value, and D₂ represents the second difference value. The power corresponding to the voltage of the first pin can be determined by the proportional relationship between the first difference value and the second difference value. For example, when the first voltage is 4.25 V, the second voltage is 3.3 V, the voltage of the first pin is 3.6 V, the first difference value is 0.95, and the second difference value is 0.3, the proportional relationship between the first difference value and the second difference value is

$$P = \frac{{D}_{2}}{{D}_{1}} \times 100 \% = \frac{0.3 V}{0.95 V} \times 100 \% = 32.$$

Therefore, it can be determined that the power corresponding to the voltage of the first pin of 3.6 V is 32%. That is, when it is detected that the voltage of the first pin of the charging chip is 3.6 V, the display power is 32%. Of course, the first relationship may also be represented in the form of the first relational table. For example, according to the foregoing formula, the first relational table may be determined by determining the power corresponding to the voltage of the first pin in the voltage range determined by the first voltage and the second voltage, so that the display power corresponding to the voltage of the first pin is determined in a table lookup manner.

In one embodiment, as illustrated in FIG. 10, determining the first relationship based on the first voltage includes actions at S1001 and S1002.

At S1001, a set second relationship is determined. In the second relationship, a first power characterizing a fully charged power of the battery corresponds to a third voltage characterizing the nominal charging cut-off voltage of the charging chip.

The set second relationship is determined. The second relationship is a correspondence between a voltage determined based on the third voltage and the power. The third voltage represents the nominal cut-off voltage of the charging chip, and is determined by a specification of the charging chip. In the second relationship, the voltage corresponding to the first power is the third voltage. The first power refers to the fully charged power of the battery. That is, a voltage corresponding to the power of the battery of 100% is the third voltage. In practical applications, the electronic device may have been configured with the correspondence between the voltage determined based on the nominal charging cut-off voltage and the power, i.e., the second relationship, before leaving factory. Therefore, the display power of the battery can be determined according to the correspondence between the voltage and the power in the second relationship. The second relationship may be in the form of the second relational table or the second relational expression.

At S1002, the first relationship is determined based on the second relationship using the first voltage.

Here, after the set second relationship is determined, the correspondence between the voltage and the power in the second relationship is adjusted based on the second relationship using the first voltage, to determine the first relationship on the basis of the second relationship. In practical applications, in response to the first voltage being different from the second voltage, the first relationship may be determined based on the second relationship using the first voltage. That is, in response to the actual charging cut-off voltage of the charging chip being different from the nominal charging cut-off voltage of the charging chip, the correspondence between the voltage and the power is determined according to the actual charging cut-off voltage of the charging chip to generate the first relationship. Therefore, the display power of the battery can be determined to display the power of the battery more accurately.

In one embodiment, the determining, based on the second relationship using the first voltage, the first relationship includes: updating, with the first voltage, the voltage corresponding to the first power in the second relationship, to obtain the first relationship.

Here, taking the relationship as an example, when the first relationship is determined based on the second relationship using the first voltage, the voltage corresponding to the first power in the second relationship is modified into the first voltage, so that a correspondence between the voltage and the fully charged power may be dynamically adjusted. When displaying the power of the battery, the power of the battery may be accurately displayed to be in the fully charged power state. As for the relational expression, the second relational expression may be determined first, the first voltage of the first pin corresponds to the first power (the fully charged power), and other voltages of the first pin correspond to the display power determined by the second relational expression. In practical applications, it may be first determined whether the first voltage is the same as the third voltage. In response to the first voltage being different from the third voltage, the voltage corresponding to the first power in the second relationship is updated with the first voltage to obtain the first relationship. When the first voltage is the same as the third voltage, the voltage corresponding to the first power in the second relationship is not required to be updated, and it is possible to directly determine the display power of the battery according to the second relationship. In other embodiments, it is also possible to first determine whether the first voltage is the same as the third voltage. When the first voltage is the same as the third voltage are the same, it is not necessary to update a corresponding relational table, and only when the first voltage is different from the third voltage, the updating is performed according the solutions provided by the corresponding embodiments to obtain the first relational table.

In one embodiment, as illustrated in FIG. 11, the determining the first relationship based on the second relationship using the first voltage includes actions at S1101 and S1102.

At S1101, a third difference value is determined. The third difference value characterizes a difference value between the first voltage and the third voltage.

Here, the third difference value is determined according to the first voltage and the third voltage. The third difference value refers to a difference value between the actual cut-off voltage of the charging chip and the nominal cut-off voltage of the charging chip. When the first voltage is the same as the third voltage, the third difference value is zero. In response to the first voltage being different from the third voltage, for example, when the first voltage is 4.25 V and the third voltage is 4.3 V, it may be determined that the third difference is 0.05 V.

At S1102, the voltage corresponding to all or part of the powers in the second relationship is updated based on the third difference value, to obtain the first relationship. The part of the powers includes the first power.

Here, taking the form of the relational table as an example, after the third difference value is determined, the voltage corresponding to each power in the second relational table is adjusted according to the third difference value, and the adjusted correspondence between the voltage and the power is determined as the first relational table. In practical applications, adjusting the voltage corresponding to each power in the second relational table is mainly to decrease the voltage corresponding to each power in the second relational table by the third difference value as a decremental amplitude. For example, the voltage corresponding to the power of 0% in the set second relational table is 3.3 V. This voltage of 3.3V is decreased based on the third difference value, and thus the updated voltage corresponding to the power of 0% is 3.25 V. The first relational table can be obtained by adjusting the voltage corresponding to each power in the set second relational table. In practical applications, when the first voltage is the same as the third voltage, the third difference value is zero, and the display power of the battery can be directly determined based on the second relational table. Therefore, a processing time and power consumption of a terminal can be saved. In addition to updating the voltage corresponding to each of the powers in the second relational table, the voltages corresponding to some of the powers in the second relational table may be updated to obtain the first relational table. When the voltages corresponding to some of the powers are updated, the voltage corresponding to the first power is at least updated, thereby ensuring that it can be determined that the display power of the battery is 100% and the power of the battery is displayed to be in the fully charged state. For example, only the voltage corresponding to the fully charged power (the power of 00%) in the second relational table and the voltage corresponding to the power at which the electronic device can not maintain the normal operation are updated. In addition, in another solution, the second relationship exists in the form of the second relational expression, and the first relational expression may be obtained according to the second relational expression to generate the corresponding relational expression, rather than generating the corresponding relational table. The corresponding relational expression is called to calculate the corresponding display power after the voltage of the first pin is detected.

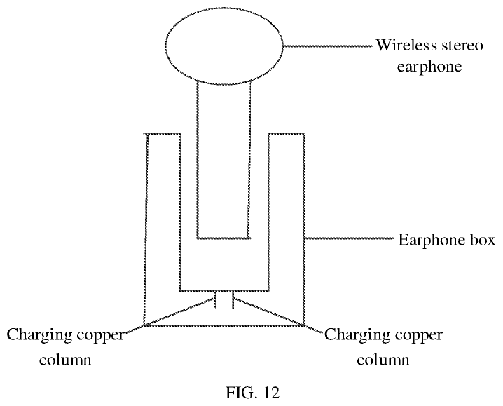

An application embodiment is further provided in the present disclosure. As illustrated in FIG. 12, a schematic diagram of a TWS earphone and an earphone box. In practical applications, in a pair of TWS earphones, two metal pins are provided at a bottom of each TWS earphone to charge the TWS earphone or communication by the earphone box. The metal pin may be disposed at a bottom of an earphone rod of the respective TWS earphone, or may be disposed below an earplug of the TWS earphone. FIG. 12 illustrates a metal pin located below the earplug of the TWS earphone. The charging box mated with the TWS earphone may receive the TWS earphone. Two charging copper columns for each TWS earphone are provided in the charging box. FIG. 12 illustrates that two charging copper columns are provided at a bottom of the charging box. After the two charging copper columns are brought into contact with the two metal pins at the bottom of the earphone rod of the TWS earphone, the TWS earphone is charged in the wireless charging manner. When the TWS earphone is placed in the earphone box for charging, an output voltage of the first pin of the corresponding charging chip may be detected when the TWS earphone is in the fully charged state, to obtain the first voltage. The first relationship between the actual power and the voltage is determined according to the first voltage. The power of the TWS earphone is displayed in real time by detecting the voltage of the first pin of the charging chip and determining the power corresponding to the voltage of the first pin in the first relationship. The power of the TWS earphone may be displayed on the charging box or on a device connected to the TWS earphone. For example, when the battery of the TWS earphone runs out, the TWS earphone is placed into the charging box for charging. At this time, the charging box may display the power of the TWS earphone in the charging process. In practical applications, in addition to displaying the power of the TWS earphone, powers of the other electronic devices may be displayed. For example, a power of a Bluetooth watch may be displayed. When applied in the TWS earphone, it is possible to reduce the following influences on the user in a case where the left and right earphones adopt charging ICs having different nominal charging cut-off voltages (namely, the third voltage). Firstly, the powers of the fully charged left and right earphones are different from each other, for example, one of the earphones is fully charged under extreme condition, and the other is only charged to 95%. Secondly, since the powers of the fully charged earphones are different, when the two earphones are used at the same time, displayed remaining battery levers of the left and right earphones are also different, which may notify the user that one of the earphones has a fast power consumption, and the other has a low power consumption, thereby misleading the user into considering that the one of the earphones is broken. Thirdly, the user may perform more frequent charging due to inaccurate display power, thereby affecting the service life of the battery. Therefore, the user experience can be improved according to the embodiments of the present disclosure.

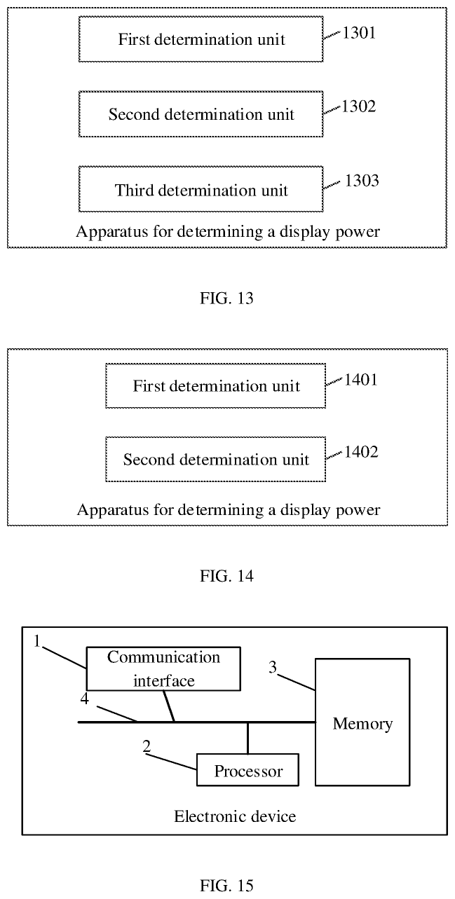

In order to implement the method for determining the display power according to the embodiments of the present disclosure, embodiments of the present disclosure further provide an apparatus for determining a display power. As illustrated in FIG. 13, the apparatus for determining the display power includes: a first determination unit 1301 configured to determine a first voltage based on a first pin of a charging chip, the first voltage characterizing a voltage of the first pin when a battery is in a fully charged state, and the first pin being a battery pin of the charging chip; and a second determination unit 1302 configured to determine a first relationship based on the first voltage, the first relationship characterizing a correspondence between the voltage of the first pin and a power of the battery; and a third determination unit 1303 configured to determine the display power of the battery based on the first relationship according to the voltage of the first pin.

In one embodiment, the second determination unit 1302 is configured to when determining the first relationship based on the first voltage: determine a first difference value characterizing a difference value between the first voltage and a second voltage, the second voltage characterizing a voltage of the first pin corresponding to a minimum power required by the battery for maintaining a normal operation of an electronic device; determine a second difference value characterizing a difference value between the voltage of the first pin and the second voltage; and determine a correspondence between the voltage of the first pin and the power in the first relationship based on a proportional relationship between the first difference value and the second difference value.

In one embodiment, the second determination unit 1302 is configured to, when determining the first relationship based on the first voltage determine a set second relationship. In the second relationship, a first power characterizing a fully charged power of the battery corresponds to a third voltage characterizing the nominal charging cut-off voltage of the charging chip; and determine the first relationship based on the second relationship using the first voltage.

In one embodiment, the second determination unit 1302 is configured to, when determining the first relationship based on the second relationship using the first voltage: update, with the first voltage, the voltage corresponding to the first power in the second relationship, to obtain the first relationship.

In one embodiment, the second determination unit 1302 is configured to, when determining the first relationship based on the second relationship using the first voltage: determine a third difference value characterizing a difference value between the first voltage and the third voltage; and update voltages corresponding to all or part of the powers in the second relationship based on the third difference value, to obtain the first relationship, the part of the powers including the first power.

In one embodiment, the first determination unit 1301 is configured to, when determining the first voltage based on the first pin of the charging chip: detect, in response to a second pin of the charging chip characterizing that the battery is in the fully charged state, the voltage of the first pin, and determine the detected voltage of the first pin as the first voltage. The second pin characterizes a charging state of the battery.

The second determination unit 1302 is configured to, when determining the first relationship based on the first voltage: determine, in response to the first voltage being different from the nominal charging cut-off voltage of the charging chip, the first relationship based on the first voltage.

In one embodiment, the first determination unit 1301 is configured to, when determining the first voltage based on the first pin of the charging chip: detect the voltage of the first pin during the charging of the battery, to obtain the detected voltage of the first pin; and determine, in response to the detected voltage of the first pin characterizing that the first pin is in a constant-voltage state, a voltage corresponding to the constant-voltage state as the first voltage.

In practical applications, the apparatus for determining the display power provided in the embodiment in FIG. 13 may be any one of the TWS earphone or a TWS sound box or other devices.

In practical applications, the first determination unit 1301, the second determination unit 1302, and the third determination unit 1303 may be implemented by a processor in the apparatus for determining the display power. Of course, the processor needs to execute a program stored in a memory to implement functions of the program modules as described above.

It should be noted that, when determining the display power by the apparatus for determining the display power provided in the embodiment of FIG. 13, only the division of the program modules is illustrated as an example. In practical applications, foregoing processing and allocation may be completed by different program modules as desired. That is, an internal structure of the apparatus is divided into different program modules to complete all or some of the processing as described above. In addition, the apparatus for determining the display power provided in the foregoing embodiments belongs to a same concept as the method for determining the display power, and thus the detailed description of the specific implementation of the apparatus may refer to that of the method embodiment, and details thereof will be omitted herein.

Embodiments of the present disclosure further provide another apparatus for determining a display power. As illustrated in FIG. 14, the apparatus for determining the display power includes a first determination unit 1401 and a second determination unit 1402. The first determination unit 1401 is configured to power a charging chip in response to a charging function of a charging chip being enabled, and collect a first voltage external to a first pin of the charging chip. The first pin is externally opened during the collecting of the first voltage, and the first pin is a battery pin of the charging chip. The second determination unit 1402 is configured to determine a first relationship based on the first voltage. The first relationship characterizes a correspondence between a voltage of the first pin and a power of a battery to allow an electronic device to determine the display power of the power based on the voltage of the first pin.

In one embodiment, the second determination unit 1402 is configured to, when determining the first relationship based on the first voltage: determine a first difference value characterizing a difference value between the first voltage and a second voltage, the second voltage characterizing a voltage of the first pin corresponding to a minimum power required by the battery for a normal operation of the electronic device; determine a second difference value characterizing a difference value between the voltage of the first pin and the second voltage; and determine a correspondence between the voltage of the first pin and the power in the first relationship based on a proportional relationship between the first difference value and the second difference value.

In one embodiment, the second determination unit 1402 is configured to, when determining the first relationship based on the first voltage: determine a set second relationship, in the second relationship, a first power characterizing a fully charged power of the battery corresponding to a third voltage characterizing the nominal charging cut-off voltage of the charging chip; and determine the first relationship based on the second relationship using the first voltage.

In one embodiment, the second determination unit 1402 is configured to, when determining the first relationship based on the second relationship using the first voltage: update, with the first voltage, a voltage corresponding to the first power in the second relationship, to obtain the first relationship.

In one embodiment, the second determination unit 1402 is configured to, when determining the first relationship based on the second relationship using the first voltage: determine a third difference value characterizing a difference value between the first voltage and the third voltage; and update voltages corresponding to all or part of the powers in the second relationship based on the third difference value, to obtain the first relationship, the part of the powers including the first power.

In practical applications, the first determination unit 1401 and the second determination unit 1402 may be implemented by a processor in the apparatus for determining the display power. Of course, the processor needs to execute a program stored in a memory to implement functions of the program modules as described above.

It should be noted that, when determining the display power by the apparatus for determining the display power provided in the embodiment of FIG. 14, only the division of the program modules is illustrated as an example. In practical applications, foregoing processing and allocation may be completed by different program modules as desired. That is, an internal structure of the apparatus is divided into different program modules to complete all or some of the processing as described above. In addition, the apparatus for determining the display power provided in the foregoing embodiments belongs to a same concept as the method for determining the display power, and thus the detailed description of the specific implementation of the apparatus may refer to that of the method embodiment, and details thereof will be omitted herein.

In the apparatuses for determining the display power provided by the above embodiments of FIG. 13 and FIG. 14, the first relationship and the second relationship may exist in the form of the relational table, i.e., the first relational table and the second relational table, or may exist in the form of the relational expression, i.e., the first relational expression and the second relational expression. Thus, the correspondence between the voltage of the first pin and the display power can be determined in the table lookup manner, or the corresponding display power can be calculated in the calculation manner according to the measured voltage of the first pin.

Based on a hardware implementation of the above program modules, and in order to implement the method in the embodiments of the present disclosure, embodiments of the present disclosure further provide an electronic device. FIG. 15 is a schematic structural diagram of hardware composition of an electronic device according to an embodiment of the present disclosure. As illustrated in FIG. 15, the electronic device includes: a communication interface 1 configured to perform information interaction with other devices such as a network device; and a processor 2 connected to the communication interface 1 to implement the information interaction with other devices. The processor 2 is configured to: when executing a computer program, perform the method for determining the display power provided by one or more technical solutions as described above. The computer program is stored on the memory 3.

Of course, in practical applications, various components in the electronic device are coupled together by using a bus system 4. It should be understood that the bus system 4 is configured to implement connection and communication between these components. In addition to a data bus, the bus system 4 further includes a power bus, a control bus, and a status signal bus. However, for clarity description, various buses are described as the bus system 4 in FIG. 15.

The memory 3 in the embodiments of the present disclosure is configured to store various types of data to support the operation of the electronic device. Examples of such data include any computer program configured to be executable on the electronic device. It should be appreciated that the memory 3 may be a transitory memory or a non-transitory memory, or may include both transitory and non-transitory memories. Here, the non-transitory memory may be a Read-Only Memory (ROM), a Programmable Read-Only Memory (PROM), an Erasable Programmable Read-Only Memory (EPROM), an Electrically Erasable Programmable Read-Only Memory (EEPROM), a ferromagnetic random access memory (FRAM), a Flash Memory, a magnetic surface memory, a compact disc, or a Compact Disc Read-Only Memory (CD-ROM). The magnetic surface memory may be either a compact disk memory or a magnetic tape memory. The transitory memory may be a Random Access Memory (RAM), which is used as an external cache. As illustrative, rather than limiting, RAMs in many forms are available, including for example a Static Random Access Memory (SRAM), a Synchronous Static Random Access Memory, a Dynamic Random Access Memory (DRAM), a Synchronous Dynamic Random Access Memory (SDRAM), a Double Data Rate Synchronous Dynamic Random Access Memory (DDR SDRAM), an Enhanced Synchronous Dynamic Random Access Memory (ESDRAM), a Synch Link Dynamic Random Access Memory (SLDRAM), or a Direct Rambus Random Access Memory (DR RAM). The memory 3 in the embodiments of the present disclosure is intended to include, but not limited to, these memories and any other suitable types of memories.

The methods disclosed in the above embodiments of the present disclosure may be applied in or implemented by the processor 2. The processor 2 may be an integrated circuit chip with signal processing capability. In an implementation, the steps of the above methods may be implemented by hardware integrated logic circuits in the processor 2 or instructions in a form of software. The above processor may be a general-purpose processor, a Digital Signal Processor (DSP), or other programmable logic devices, a discrete gate or transistor logic device, a discrete hardware component, or the like. The methods, steps, and logical block diagrams disclosed in the embodiments of the present disclosure can be implemented or performed by the processor 2. The general-purpose processor may be a microprocessor or any conventional processor. The steps of the methods disclosed in the embodiments of the present disclosure may be directly embodied as being performed and completed by a hardware decoding processor, or by a combination of hardware and software modules in the decoding processor. The software modules may be located on the storage medium. The storage medium is located in the memory 3, and the processor 2 can read information from the memory 3 and implement the steps of the above methods by combining with its hardware.

The processor 2, when executing the program, implements a corresponding process in each method of the embodiments of the present disclosure. For brevity, details are not omitted herein.

In the embodiments of the present disclosure, the electronic device includes a wireless earphone. The wireless earphone may be the pair of TWS earphones as illustrated in FIG. 12. Each TWS earphone in the pair of TWS earphones can display the power through each method in the embodiments of the present disclosure.

In an exemplary embodiment, embodiments of the present disclosure further provide the storage medium, i.e., a computer storage medium, and in some embodiments, a computer-readable storage medium, for example, including the memory 3 having the computer program stored thereon. The above computer program can be executed by the processor 2 to implement the steps in the foregoing method. The computer readable storage medium may be a memory such as a FRAM, a ROM, a PROM, an EPROM, an EEPROM, a FLASH MEMORY, a magnetic surface memory, a compact disc, or a CD-ROM.

In several embodiments provided by the present disclosure, it should be understood that, the disclosed apparatus, terminal, and method may be implemented in other ways. The device embodiments described above are merely illustrative. For example, the units are merely divided according to logic functions, and may be divided in other ways in actual implementation. For example, a plurality of units or components may be combined or may be integrated into another system, or some features may be ignored or not be executed. In addition, the mutual coupling or direct coupling or communication connection between the various components illustrated or discussed may be a direct coupling or communication connection via some interfaces, devices or units, and may be an electrical, mechanical, or other forms.

The units described as separate parts may be or not be physically separated. Parts illustrated as units may be or not be physical units. That is, the parts may be located in one location, or may be distributed on a plurality of network units. Some or all of the units may be selected as desired to achieve the objects of solutions of the embodiments.

In addition, all the functional units in respective embodiments of the present disclosure may be integrated into one processing unit, or each of the respective units may be one separate unit, or two or more units may be integrated into one unit. The above integrated unit may be implemented in the form of hardware, or in the form of a combination of hardware and software functional units.

Those of ordinary skill in the art could understand that, all or part of the steps of the foregoing method embodiments may be implemented by a program instruction-related hardware. The above program may be stored on a computer-readable storage medium. The program, when executed, implements the steps in the above method embodiments. The above storage medium includes various media having program codes stored thereon, such as a mobile storage device, a ROM, a RAM, a magnetic disk, or a compact disc.

In some embodiment, when the above integrated unit is implemented in the form of the software functional module and sold or used as an independent product, the integrated unit may also be stored in a computer-readable storage medium. In view of the above, the technical solutions of the embodiments of the present disclosure essentially, or the part contributing to the related art may be embodied in a form of a software product. The computer software product is stored in the storage medium, and includes several instructions for instructing a terminal (which may be a personal computer, a server, or the network device) to perform all or part of the methods described in the embodiments of the present disclosure. The above storage medium includes various medium having the program code stored thereon, such as a mobile storage device, a ROM, a RAM, a magnetic disk, or the compact disc.

It should be noted that in the examples of the present disclosure, expressions such as “first” and “second” are used to distinguish similar objects, rather than describing a specific sequence or order.

In addition, the technical solutions described in the embodiments of the present disclosure can be combined arbitrarily without mutual contradiction.

While the specific embodiments of the present disclosure have been described above, the scope of the present disclosure is not limited to these embodiments. Various variants and alternatives easily conceived by those skilled in the art with the technical scope of the present disclosure shall fall within the scope of the present disclosure. Therefore, the scope of present disclosure should be defined by the appended claims.

What is claimed is:

1. A method for determining a display power, the method comprising:
determining, based on a first pin of a charging chip, a first voltage characterizing a voltage of the first pin when a battery is in a fully charged state, the first pin being a battery pin of the charging chip;
determining, based on the first voltage, a first relationship characterizing a correspondence between the voltage of the first pin and a power of the battery; and
determining, based on the first relationship, the display power of the battery using the voltage of the first pin.

2. The method for determining the display power according to claim 1, wherein said determining, based on the first voltage, the first relationship, comprises:
determining a first difference value characterizing a difference value between the first voltage and a second voltage, the second voltage characterizing a voltage of the first pin corresponding to a minimum power required by the battery for maintaining a normal operation of an electronic device;
determining a second difference value characterizing a difference value between the voltage of the first pin and the second voltage; and
determining, based on a proportional relationship between the first difference value and the second difference value, a correspondence between the voltage of the first pin and the power in the first relationship.

3. The method for determining the display power according to claim 1, wherein said determining, based on the first voltage, the first relationship comprises:
determining a set second relationship, wherein in the second relationship, a first power characterizing a fully charged power of the battery corresponds to a third voltage characterizing a nominal charging cut-off voltage of the charging chip; and
determining, based on the second relationship, the first relationship using the first voltage.

4. The method for determining the display power according to claim 3, wherein said determining, based on the second relationship, the first relationship using the first voltage comprises:
updating, with the first voltage, the voltage corresponding to the first power in the second relationship, to obtain the first relationship.

5. The method for determining the display power according to claim 3, wherein said determining, based on the second relationship, the first relationship using the first voltage comprises:
determining a third difference value characterizing a difference value between the first voltage and the third voltage; and
updating, based on the third difference value, voltages corresponding to all or part of powers in the set second relationship, to obtain the first relationship, wherein the part of the powers comprises the first power.

6. The method for determining the display power according to claim 1, wherein:
said determining, based on the first pin of the charging chip, the first voltage comprises:
detecting, in response to a second pin of the charging chip characterizing that the battery is in the fully charged state, the voltage of the first pin, and determining the detected voltage of the first pin as the first voltage, the second pin characterizing a charging state of the battery, and
said determining, based on the first voltage, the first relationship comprises:
determining, in response to the first voltage being different from a nominal charging cut-off voltage of the charging chip, the first relationship based on the first voltage.

7. The method for determining the display power according to claim 1, wherein said determining, based on the first pin of the charging chip, the first voltage comprises:
detecting the voltage of the first pin during charging of the battery, to obtain the detected voltage of the first pin; and
determining, in response to the detected voltage of the first pin characterizing that the first pin is in a constant-voltage state, a voltage corresponding to the constant-voltage state as the first voltage.

8. A method for determining a display power, the method comprising:
powering a charging chip in response to a charging function of the charging chip being enabled, and collecting a first voltage external to a first pin of the charging chip, wherein the first pin is externally opened during the collecting of the first voltage, and the first pin is a battery pin of the charging chip; and
determining, based on the first voltage, a first relationship characterizing a correspondence between a voltage of the first pin and a power of a battery, to allow an electronic device to determine the display power of the battery based on the voltage of the first pin.

9. The method for determining the display power according to claim 8, wherein said determining, based on the first voltage, the first relationship comprises:
determining a first difference value characterizing a difference value between the first voltage and a second voltage, the second voltage characterizing a voltage of the first pin corresponding to a minimum power required by the battery for maintaining a normal operation of the electronic device;
determining a second difference value characterizing a difference value between the voltage of the first pin and the second voltage; and
determining, based on a proportional relationship between the first difference value and the second difference value, a correspondence between the voltage of the first pin and the power in the first relationship.

10. The method for determining the display power according to claim 8, wherein said determining, based on the first voltage, the first relationship comprises:
determining a set second relationship, wherein in the second relationship, a first power characterizing fully charged power of the battery corresponds to a third voltage characterizing a nominal charging cut-off voltage of the charging chip; and
determining, based on the second relationship, the first relationship using the first voltage.

11. The method for determining the display power according to claim 10, wherein said determining, based on the second relationship, the first relationship using the first voltage comprises:
updating, with the first voltage, the voltage corresponding to the first power in the second relationship, to obtain the first relationship.

12. The method for determining the display power according to claim 10, wherein said determining, based on the second relationship, the first relationship using the first voltage comprises:
determining a third difference value characterizing a difference value between the first voltage and the third voltage; and
updating, based on the third difference value, voltages corresponding to all or part of powers in the set second relationship, to obtain the first relationship, wherein the part of the powers comprises the first power.

13. An electronic device, comprising:
a processor; and
a memory storing a computer program executable on the processor,
wherein the processor is configured to implement, when executing the computer program, steps of:
determining, based on a first pin of a charging chip, a first voltage characterizing a voltage of the first pin when a battery is in a fully charged state, the first pin being a battery pin of the charging chip;
determining, based on the first voltage, a first relationship characterizing a correspondence between the voltage of the first pin and a power of the battery; and
determining, based on the first relationship, a display power of the battery using the voltage of the first pin.

14. The electronic device according to claim 13, wherein said determining, based on the first voltage, the first relationship, comprises:
determining a first difference value characterizing a difference value between the first voltage and a second voltage, the second voltage characterizing a voltage of the first pin corresponding to a minimum power required by the battery for maintaining a normal operation of an electronic device;
determining a second difference value characterizing a difference value between the voltage of the first pin and the second voltage; and
determining, based on a proportional relationship between the first difference value and the second difference value, a correspondence between the voltage of the first pin and the power in the first relationship.

15. The electronic device according to claim 13, wherein said determining, based on the first voltage, the first relationship comprises:
determining a set second relationship, wherein in the second relationship, a first power characterizing a fully charged power of the battery corresponds to a third voltage characterizing a nominal charging cut-off voltage of the charging chip; and
determining, based on the second relationship, the first relationship using the first voltage.

16. The electronic device according to claim 13, further comprising a wireless earphone.

17. An electronic device, comprising:
a processor; and
a memory storing a computer program executable on the processor,
wherein the processor is configured to implement, when executing the computer program, steps of the method for determining the display power according to claim 8.

18. The electronic device according to claim 17, further comprising a wireless earphone.

19. A storage medium, having a computer program stored thereon,
wherein the computer program, when executed by a processor, implements steps of the method for determining the display power according to claim 1.

20. A storage medium, having a computer program stored thereon,
wherein the computer program, when executed by a processor, implements steps of the method for determining the display power according to claim 8.
